(19) United States
(12) Patent Application Publication
(10) Pub. No.: US 2003/0175620 A1
(43) Pub. Date: Sep. 18, 2003

(54) Chemical amplification type positive resist composition

(76) Inventors: Kouji Toishi, Osaka (JP); Yoshiko Miya, Kyoto-shi (JP); Yasunori Uetani, Osaka (JP)

Correspondence Address: BIRCH STEWART KOLASCH & BIRCH, PO BOX 747, FALLS CHURCH, VA, 22040-0747, US

(21) Appl. No.: 10/327,138

(22) Filed: Dec. 24, 2002

(30) Foreign Application Priority Data
Dec. 27, 2001 (JP) 2001-395887

(51) Int. Cl. G03F 7/004

(52) U.S. Cl. 430/280.1

(57) ABSTRACT

The present invention provides a chemical amplification type positive resist composition comprising a resin having structural units of the following general formulae (I) and (II) and insoluble or poorly soluble itself in an alkali aqueous solution but becoming soluble in an alkali aqueous solution by the action of an acid; an acid generating agent; and a multifunctional epoxy compound:

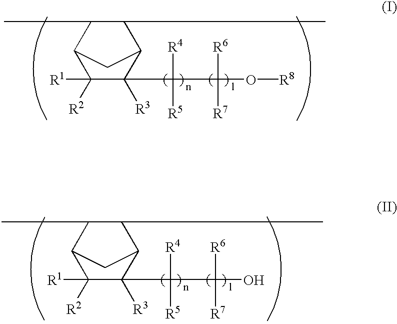

wherein, R¹, R² and R³ represent each independently hydrogen, halogen, hydroxyl group, alkyl group having 1 to 14 carbon atoms, alicyclic group or lactone ring group,

wherein at least one hydrogen on the alicyclic group or on the lactone ring group may independently be substituted by halogen, hydroxyl group or alkyl group and at least one hydrogen on the alkyl group may independently be substituted by halogen, hydroxyl group or alicyclic ring group;

n and 1 represent each independently an integer of 0 to 4;

R⁴ and R⁵ represent each independently hydrogen or alkyl group having 1 to 4 carbon atoms; and

either or both of R⁶ and R⁷ represent fluoroalkyl group having 1 to 6 carbon atoms and when both of R⁶ and R7 do not represent said fluoroalkyl group, rest of R⁶ and R⁷ represents hydrogen or alkyl group having 1 to 6 atoms; and

R⁸ represents an acid-unstable group dissociating in the presence of an acid.

### BACKGROUND OF THE INVENTION

### FIELD OF THE INVENTION

The present invention relates to a chemical amplification type positive resist composition.

For fine processing of semiconductors, a lithography process using a resist composition is usually adopted, and in lithography, it is theoretically possible to increase resolution higher when exposure wavelength is shorter as represented by the Rayleigh diffraction limitation formula. As the exposure light source for lithography used for production of semiconductors, there are g ray having a wavelength of 436 nm, i ray having a wavelength of 365 nm, KrF excimer laser having a wavelength of 248 nm and ArF excimer laser having a wavelength of 193 nm, developed in this order, the wavelength becoming shorter year by year. Further, as the exposure light source of the next generation, F₂ excimer laser having a wavelength of 157 nm is promising. For exposure to KrF excimer laser and ArF excimer laser, what is called chemical amplification type resists utilizing the catalytic action of an acid generated by exposure are often used due to excellent sensitivity. Further, also for exposure to F₂ excimer laser, there is a high possibility of use of chemical amplification type resists due to excellent sensitivity.

Resins used for resist may change depending on the light source in the tendency to use shorter exposure wavelength. Polyvinylphenolic resins for KrF excimer laser lithography, and acrylic or cycloolefinic resins for ArF excimer laser lithography are mainly used. Norbornene based resins are proposed for F₂ excimer laser lithography.

However, even when said resins described above are used, resist compositions do not have sufficient durability against dry etching, and it is necessary to provide resist compositions having higher durability against dry-eching.

An object of the present invention is to provide chemical amplification type positive resist composition which is suitable for ArF, KrF and F₂ excimer laser lithography and which show excellent in resist properties such as sensitivity and resolution, especially excellent in durability against dry etching.

The present inventors have found that a chemical amplification type positive resist composition, which contains a resin having specific structural units and multifunctional epoxy compound, has excellent properties not only in durability against dry etching but also in various performances as resist, leading to completion of the present invention.

### SUMMARY OF THE INVENTION

Namely, the present invention relates to the following inventions.

<1> A chemical amplification type positive resist composition comprising a resin having structural units of the following general formulae (I) and (II) and insoluble or poorly soluble itself in an alkali aqueous solution but becoming soluble in an alkali aqueous solution by the action of an acid; an acid generating agent; and a multifunctional epoxy compound:

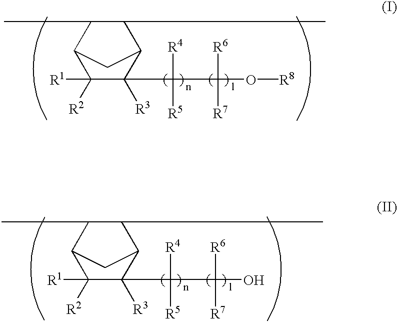

wherein, R¹, R² and R³ represent each independently hydrogen, halogen, hydroxyl group, alkyl group having 1 to 14 carbon atoms, alicyclic group or lactone ring group,

wherein at least one hydrogen on the alicyclic group or on the lactone ring group may independently be substituted by halogen, hydroxyl group or alkyl group and at least one hydrogen on the alkyl group may independently be substituted by halogen, hydroxyl group or alicyclic ring group;

n and 1 represent each independently an integer of 0 to 4;

R⁴ and R⁵ represent each independently hydrogen or alkyl group having 1 to 4 carbon atoms; and

either or both of R⁶ and R⁷ represent fluoroalkyl group having 1 to 6 carbon atoms and when both of R⁶ and R⁷ do not represent said fluoroalkyl group, rest of R⁶ and R⁷ represents hydrogen or alkyl group having 1 to 6 atoms; and

R⁸ represents an acid-unstable group dissociating in the presence of an acid.

<2> The chemical amplification type positive resist composition according to <1>, wherein said resin further having structural unit of the following general formula (III):

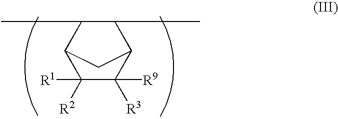

wherein R¹, R², R³, R⁴, R⁵, R⁶, R⁷, and R⁸ represent the same as defined above; and

R⁹ represent hydrogen, halogen, alkyl group having 1 to 14 carbon atoms, alicyclic group or lactone ring group,

wherein at least one hydrogen on the alicyclic group or the lactone ring group may independently be substituted by halogen or alkyl group and at least one hydrogen on the alkyl group may independently be substituted by halogen, or alicyclic ring group.

<3> The chemical amplification type positive resist composition according to <1> or <2>, wherein said multifunctional epoxy compound is at least one compound selected from the group consisting of epoxy compounds of the following general formula (V):

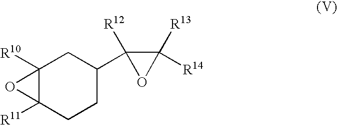

wherein R¹⁰, R¹¹, R¹² and R¹⁴ represent each independently hydrogen, methyl or ethyl.

<4> The chemical amplification type positive resist composition according to <1> or <2>, wherein said multifunctional epoxy compound is at least one compound selected from the group consisting of epoxy compounds of the following general formula (VI):

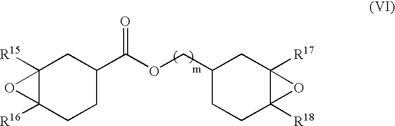

wherein R¹⁵, R¹⁶, R¹⁷ and R¹⁸ represent each independently hydrogen, methyl or ethyl and m represents an integer of 1 to 8.

<5> The chemical amplification type positive resist composition according to <1> or <2>, wherein said multifunctional epoxy compound is at least one compound selected from the group consisting of epoxy compounds of the following general formula (VII):

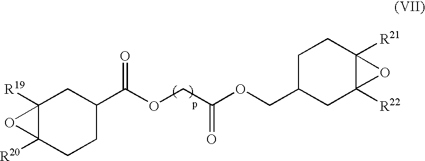

Wherein R¹⁹, R²⁰, R²¹ and R²² represent each independently hydrogen, methyl or ethyl and p represents an integer of 1 to 8.

<6> The chemical amplification type positive resist composition according to <1> or <2>, wherein said multifunctional epoxy compound is an epoxy compound of the formula (V), wherein R¹⁰ and R¹² represent methyl, and R¹¹, R¹³ and R¹⁴ represent hydrogen.

<7> The chemical amplification type positive resist composition according to any one of <1> to <6>, wherein the content of the acid generating agent is from 0.1 to 20 parts by weight and the content of the multifunctional epoxy compound is from 0.01 to 5 parts by weight based on 100 parts of the resin insoluble or poorly soluble itself in an alkali aqueous solution but becoming soluble in an alkali aqueous solution by the action of an acid.

<8> The chemical amplification type positive resist composition according to any one of <1> to <7>, wherein the content of the structural unit of the formula (I) is from 0.15 to 0.5 mole based on one mole of total content of structural units of the formulae (I), (II) and (III).

<9> The chemical amplification type positive resist composition according to any one of <1> to <8>, which further comprises a basic compound as a quencher.

<10> The chemical amplification type positive resist composition according to <9>, wherein the content of the basic compound is from 0.001 to 1 part by weight based on 100 parts by weight of the resin insoluble or poorly soluble itself in an alkali aqueous solution but becoming soluble in an alkali aqueous solution by the action of an acid.

<11> The chemical amplification type positive resist composition according to any one of <1> to <10>, wherein the resin having the structural units of the formulae (I) and (II) is obtained by partially substituting an acid-unstable group dissociating in the presence of an acid for hydrogen of hydroxyl group in a resin having a structural unit of the formula (II).

### EMBODIMENTS OF THE INVENTION

The resin component in the present invention is a resin having the structural units of the formulae (I) and (II) and if necessary further having the structural unit of the formula (III) and insoluble or poorly soluble itself in an alkali aqueous solution but becoming soluble in an alkali aqueous solution by the action of an acid (in the present specification, referred to as “the present resin component”).

Though the present resin component can further have other structural unit(s) such as the structural unit of the following formulae:

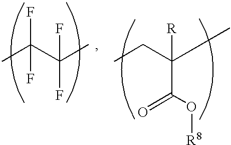

wherein R represents hydrogen, fluorine, methyl or cyano, and R⁸ represent the same as defined above, as long as the effect of the present invention is not deteriorated, total content of the structural units of the formulae (I), (II) and (III) is usually not less than 50% mol, preferably not less than 75% by mol based on total mol of the present resin component. More preferably the present resin component consists essentially of the structural units of the formulae (I), (II) and (III).

In the formulae (I), (II) and (III), R¹, R² and R³ represent each independently hydrogen, halogen, hydroxyl group, alkyl group having 1 to 14 carbon atoms, alicyclic group or lactone ring group. At least one hydrogen on the alicyclic group or on the lactone ring group may independently be substituted by halogen, hydroxyl group or alkyl group. At least one hydrogen on the alkyl group may independently be substituted by halogen, hydroxyl group or alicyclic ring group and the alkyl group may be straight chained, cyclic or branched. n and 1 represent each independently an integer of 0 to 4.

R⁴ and R⁵ represent each independently hydrogen or alkyl group having 1 to 4 carbon atoms. Either or both of R⁶ and R⁷ represent fluoroalkyl group having 1 to 6 carbon atoms and when both of R⁶ and R⁷ do not represent said fluoroalkyl group, rest of R⁶ and R⁷ represents hydrogen or alkyl group having 1 to 6 atoms. R⁸ represents an acid-unstable group dissociating in the presence of an acid.

R⁹ represent hydrogen, halogen, alkyl group having 1 to 14 carbon atoms, alicyclic group or lactone ring group. At least one hydrogen on the alicyclic group or on the lactone ring group may independently be substituted by halogen or alkyl group. At least one hydrogen on the alkyl group may independently be substituted by halogen or alicyclic ring group and the alkyl group may be straight chained, cyclic or branched.

Examples of the halogen include fluorine, chlorine, bromine, and the like. Examples of the alkyl having 1 to 14 carbons include methyl, ethyl, propyl, isopropyl, butyl, tert-butyl, and the like. Examples of the cyclic group includes cyclopentyl, cyclohexyl, and the like. Examples of the lactone ring group include tetrahydro-2-oxo-3-furyl, and the like.

Examples of the halogenated alkyl group include fluoromethyl, difluoromethyl, trifluoromethyl, and the like.

Examples of the hydroxylated alkyl group include hydroxymethyl, hydroxyethyl, and the like.

Examples of halogenated, hydroxylated or alkylated alicyclic group and halogenated, hydroxylated or alkylated lactone ring group include hydroxy-tetrahydro-2-oxo-3-furyl, methyl-tetrahydro-2-oxo-3-furyl, and the like.

Examples of the alkyl group having 1 to 4 carbon atoms in R⁴ and R⁵include methyl, ethyl, propyl, isopropyl, butyl, tert-butyl, and the like.

Examples of the alkyl group having 1 to 6 carbon atoms substituted by at least one fluorine include fluoromethyl, difluoromethyl, trifluoromethyl, 2,2,2-trifluoroethyl, perfluoroethyl, —C(CF₃)₃, and the like, and examples of the alkyl having 1 to 6 carbon atoms include methyl, ethyl, propyl, isopropyl, butyl, tert-butyl, and the like.

R⁸ is an acid-unstable group dissociating in the presence of an acid, and specifically the group dissociating in the presence of an acid to cause the present resin component to become soluble in an alkali aqueous solution.

The acid-unstable group dissociating in the presence of an acid can be various known protecting groups.

Examples of the acid unstable group include groups in which quaternary carbon is bonded to an oxygen atom such as a tert-butyl, tert-butoxycarbonylmethyl and the like; groups of acetal type such as tetrahydro-2-pyranyl, tetrahydro-2-furyl, 1-ethoxyethyl, 1-(2-methylpropoxy)ethyl, 1-(2-methoxyethoxy)ethyl, 1-(2-acetoxyethoxy)ethyl, 1-[2-(1-adamantyloxy)ethoxy]ethyl, 1-[2-(1-adamantanecarbonyloxy)ethoxy]ethyl, methoxymethyl, ethoxymethyl, pivaloyloxymethyl, methoxyethoxymethyl, benzyloxymethyl and the like.

Particularly, it is preferable to use groups of acetal type such as methoxymethyl, ethoxymethyl and the like, since they can be easily available or synthesized.

The acid-unstable group shall be dissociated by the action of an acid and substituted by hydrogen, and the present resin component shall become alkali-soluble.

The acid-unstable group can be introduced easily into a resin by the conventional protective group-introduction reaction or copolymerization using, as one monomer, an unsaturated compound having such acid-unstable group.

In the structural unit of (I), it is preferable to be the structural unit wherein at least one of R¹ to R⁵ represents trifluoromethyl group in addition to at least one of R⁶ and R⁷ and the structural unit represented by the following formula (IV):

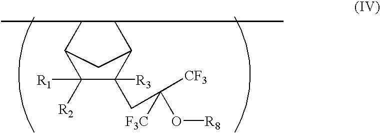

Wherein, R¹, R², R³ and R⁸ means the same as defined above, since transmittance under vacuum ultraviolet rays typified by 157 nm is higher.

The present resin component can be obtained by polymerization according to conventional polymerization reaction. Namely, polymerization can be conducted by mixing monomers which can derive the above-mentioned structural units with a catalyst, and stirring the mixture at suitable temperature, in the presence or absence of a solvent. The polymer thus obtained can be purified by precipitation in a suitable solvent.

As the present resin component, it can be the resins obtained by partially substituting an acid-unstable group dissociating in the presence of an acid for hydrogen of hydroxyl group in a resin having a structural unit of the formula (II).

It is generally preferable that the content of the structural unit of the formula (I) is from 0.15 to 0.5 mole based on one mole of total content of the structural units of the formula (I), (II) and (III), though the content varies depending on the kind of radiation for patterning exposure, the kind of a group dissociating by the action of an acid (R⁸) and the like.

Examples of the structural unit of the formula (I) include the following formulae:

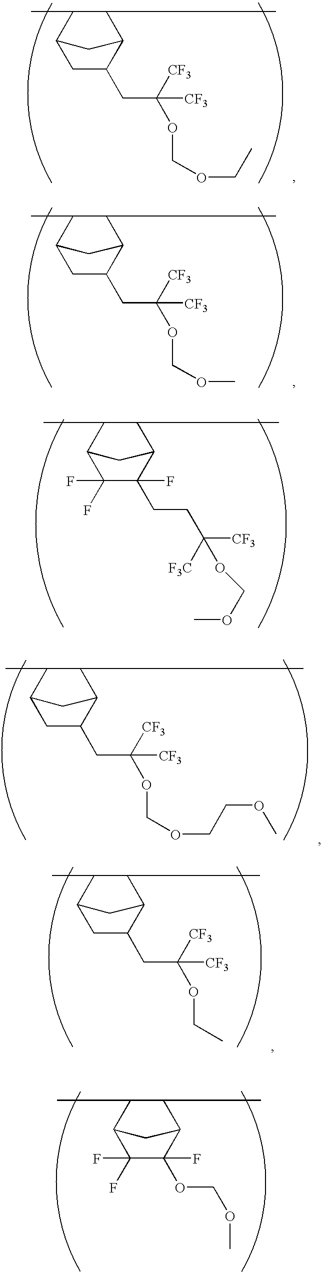

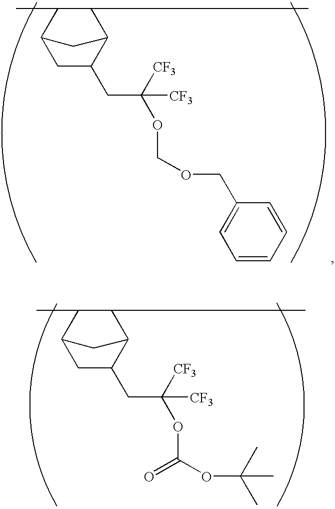

Examples of the structural unit of the formula (II) include the following formulae:

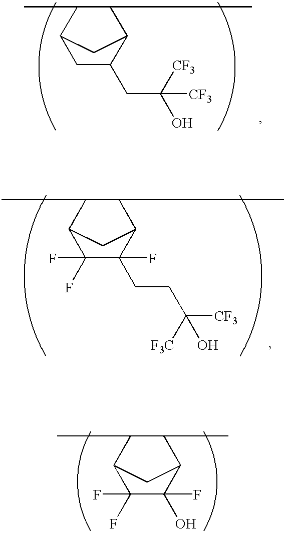

Examples of the structural unit of the formula (III) include the following formula:

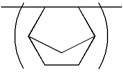

As the preferred combinations of the structural units of the formulae (I) and (II) or the combinations of the structural units of the formulae (I), (II) and (III) include the following combinations of the formulae:

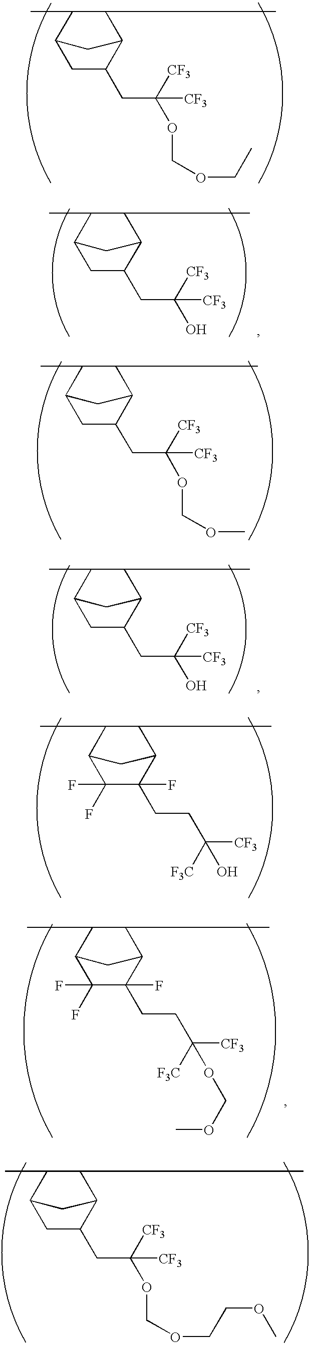

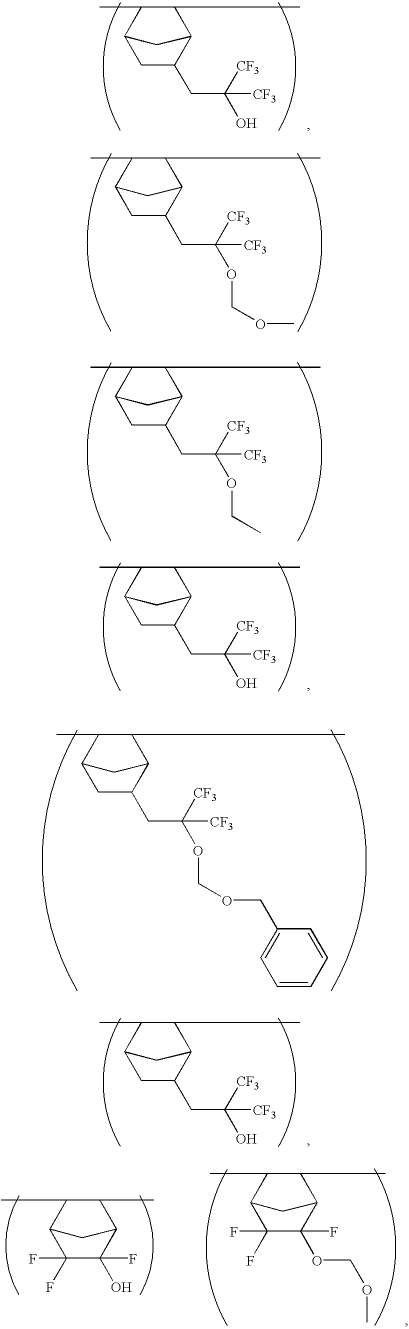

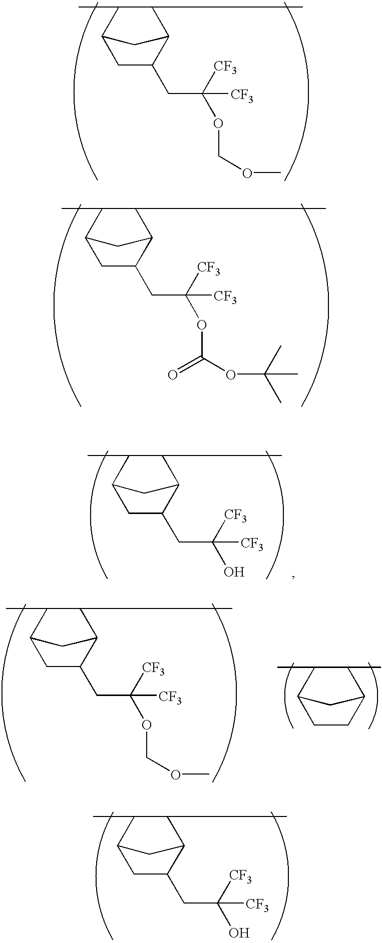

The acid generating agent used in the present invention is not particularly restricted as long as the acid generating agent is decomposed to generate an acid by allowing radiations such as light, electron beam and the like to act on the acid generating agent itself or a resist composition containing the acid generating agent.

An acid generated from the acid generating agent acts on the present resin component to dissociate a group dissociating by the action of an acid in the present resin component.

Examples of the acid generating agent include onium salt compounds, organohalogen compounds, sulfone compounds, sulfonate compounds and the like.

Specific examples of the acid generating agents include the following compounds.

Diphenyliodonium trifluoromethanesulfonate,

4-methoxyphenylphenyliodinium hexafluoroantimonate,

4-methoxyphenylphenyliodinium trifluoromethanesulfonate,

bis(4-tert-butylphenyl)iodonium tetrafluoroborate

bis(4-tert-butylphenyl)iodonium perfluorobutanesulfonate

bis(4-tert-butylphenyl)iodonium hexafluorophosphate,

bis(4-tert-butylphenyl)iodonium hexafluoroantimonate

bis(4-tert-butylphenyl)iodonium trifluoromethanesulfonate,

bis(4-tert-butylphenyl)iodonium camphorsulfonate,

triphenylsulfonium hexafluorophosphate,

triphenylsulfonium hexafluoroantimonate,

triphenylsulfonium trifluoromethanesulfonate,

4-methoxyphenyldiphenylsulfonium hexafluoroantimonate,

4-methoxyphenyldiphenylsulfonium trifluoromethanesulfonate,

p-tolyldiphenylsulfonium trifluoromethanesulfonate,

p-tolyldiphenylsulfonium perfluorobutanesulfonate,

p-tolyldiphenylsulfonium perfluorooctanesulfonate,

2,4,6-trimethylphenyldiphenylsulfonium trifluoromethanesulfonate,

4-tert-butylphenyldiphenylsulfonium trifluoromethanesulfonate,

4-phenylthiophenyldiphenylsulfonium hexafluorophosphate,

4-phenylthiophenyldiphenylsulfonium hexafluoroantimonate,

1-(2-naphthoylmethyl)thiolanium hexafluoroantimonate,

1-(2-naphthoylmethyl)thiolanium trifluoromethanesulfonate,

4-hydroxy-1-naphthyldimethylsulfonium hexafluoroantimonate,

4-hydroxy-1-naphthyldimethylsulfonium trifluoromethanesulfonate,

2-methyl-4,6-bis(trichloromethyl)-1,3,5-triazine,

2,4,6-tris(trichloromethyl)-1,3,5-triazine

2-phenyl-4,6-bis(trichloromethyl)-1,3,5-triazine,

2-(4-chlorophenyl)-4,6-bis(trichloromethyl)-1,3,5-triazine,

2-(4-methoxyphenyl)-4,6-bis(trichloromethyl)-1,3,5-triazine,

2-(4-methoxy-1-naphthyl)-4,6-bis(trichloromethyl)-1,3,5-triazine,

2-(benzo[d][1,3]dioxolan-5-yl)-4,6-bis(trichloromethyl)-1,3,5-triazine,

2-(4-methoxystyryl)-4,6-bis(trichloromethyl)-1,3,5-triazine,

2-(3,4,5-trimethoxystyryl)-4,6-bis(trichloromethyl)-1,3,5-triazine,

2-(3,4-dimethoxystyryl)-4,6-bis(trichloromethyl)-1,3,5-triazine,

2-(2,4-dimethoxystyryl)-4,6-bis(trichloromethyl)-1,3,5-triazine,

2-(2-methoxystyryl)-4,6-bis(trichloromethyl)-1,3,5-triazine,

2-(4-butoxystyryl)-4,6-bis(trichloromethyl)-1,3,5-triazine,

2-(4-pentyloxystyryl)-4,6-bis(trichloromethyl)-1,3,5-triazine,

1-benzoyl-1-phenylmethyl p-toluenesulfonate (generally called “benzoin tosylate”),

2-benzoyl-2-hydroxy-2-phenylethyl p-toluenesulfonate (generally called α-methylolbenzoin tosylate),

1,2,3-benzene-triyl tris(methanesulfonate),

2,6-dinitrobenzyl p-toluenesulfonate,

2-nitrobenzyl p-toluenesulfonate,

4-nitrobenzyl p-toluenesulfonate,

diphenyl disulfone,

di-p-tolyl disulfone

bis(phenylsulfonyl)diazomethane,

bis(4-chlorophenylsulfonyl)diazomethane,

bis(p-tolylsulfonyl)diazomethane,

bis(4-tert-butylphenylsulfonyl)diazomethane,

bis(2,4-xylylsulfonyl)diazomethane,

bis(cyclohexylsulfonyl)diazomethane,

(benzoyl)(phenylsulfonyl)diazomethane,

N-(phenylsulfonyloxy)succinimide,

N-(trifluoromethylsulfonyloxy)succinimide,

N-(trifluoromethylsulfonyloxy)phthalimide,

N-(trifluoromethylsulfonyloxy)-5-norbornene-2,3-dicarboxyimide,

N-(trifluoromethylsulfonyloxy)naphthalimide,

N-(10-camphorsulfonyloxy)naphthalimide and the like.

The positive resist composition of the present invention may further contain a basic compound as, so called quencher. Said basic compounds may be a basic nitrogen containing compounds such as amines.

It is preferable to contain a basic compound in the positive resist composition of the present composition because the deterioration in ability due to deactivation of an acid followed by post exposure delay can be diminished. Specific examples of the basic compound used as a quencher include compounds of the following formulae.

(Compound 1)

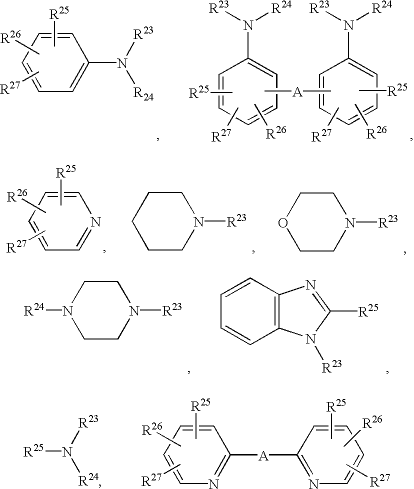

(Compound 2)

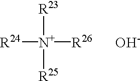

In the above formulae, R²³, R²⁴, R²⁵, R²⁶ and R²⁷ represent each independently hydrogen, alkyl, cycloalkyl or aryl provided that none of R²³, R²⁴, R²⁵, R²⁶ and R²⁷ in the compound 2 is hydrogen. At least one hydrogen on the alkyl, cycloalkyl or aryl may be independently substituted by hydroxyl group, amino group or alkoxy group having 1 to 6 carbon atoms. At least one hydrogen on the amino group may be substituted by alkyl group having 1 to 18 carbon atoms. In R²³, R²⁴, R²⁵, R²⁶ and R²⁷, the alkyl preferably has about 1 to 8 carbon atoms, the cycloalkyl preferably has about 5 to 10 carbon atoms, and the aryl preferably has about 6 to 10 carbon atoms.

A represents alkylene, carbonyl, imino, sulfide or disulfide. The alkylene preferably has about 2 to 6 carbon atoms.

R²³, R²⁴, R²⁵, R²⁶ and R²⁷ may each independently be straight chained or branched.

In view of resolution, it is preferable to use Compound 2 as a quencher.

Examples of the compound 2 include tetramethylammonium hydroxide, tetrabutylammonium hydroxide, tetrahexylammonium hydroxide, tetraoctylammonium hydroxide, phenyltrimethylammonium hydroxide, 3-trifluoromethylphenyltrimethylammonium hydroxide and the like.

Examples of the compound 1 include hexylamine, heptylamine, octylamine, nonylamine, decylamine, aniline,2-, 3- or 4-methylaniline, 4-nitroaniline, 1- or 2-naphtylamine, ethylenediamine, tetramethylenediamine, hexamethylenediamine, 4,4′-diamino-1,2-diphenylethane, 4,4′-diamino-3,3′-dimethyldiphenylmethane, 4,4′-diamino-3,3′-diethyldiphenylmethane, dibutylamine, dipentylamine, dihexylamine, diheptylamine, dioctylamine, dinonylamine, didecylamine, N-methylaniline, piperidine, diphenylamine, triethylamine, trimethylamine, tripropylamine, tributylamine, tripentylamine, trihexylamine, trihexylamine, triheptylamine, trioctylamine, trinonylamine, tridecylamine, methyldibutylamine, methyldipentylamine, methyldihexylamine, methyldicyclohexylamine, methyldiheptylamine, ethyldioctylamine, ethyldinonylamine, ethyldidecylamine, dicyclohexylmethylamine, tris[2-(2-methoxyethoxy)ethyl]amine, triisopropanolamine, N,N-dimethylaniline, 2,6-isopropylaniline, imidazole, pyridine, 4-methylpyridine, 4-methyimidazole, bipyridine, 2,2′-dipyridylamine, di-2-pyridyl ketone, 1,2-di(2-pyridyl)ethane, 1,2-di(4-pyridyl)ethane, 1,3-di(4-pyridyl)propane, 1,2-bis(2-pyridyl)ethylene, 1,2-bis(4-pyridyl)ethylene, 1,2-bis(2-pyridyloxy)ethane, 4,4′-dipyridyl sulfide, 4,4′-dipyridyl disulfide, 1,2-bis(4-pyridyl)ethylene, 2,2′-dipicolylamine, 3,3′-dipicolylamine and the like.

The content of the multifunctional epoxy compound in the resist composition of the present invention is preferably from 0.01 to 5 parts by weight based on 100 parts by weight of the present resin component.

Examples of the multifunctional epoxy compound may be at least one compound selected from the group consisting of epoxy compounds of the following general formula (V):

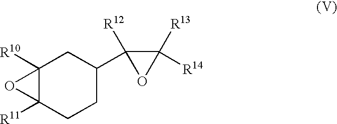

wherein R¹⁰, R¹¹, R¹² and R¹⁴ represent each independently hydrogen, methyl or ethyl.

Specific example of the epoxy compound of the formula (V) is the epoxy compound wherein R¹⁰ and R¹² are methyl, and R¹¹, R¹³ and R¹⁴ are hydrogen, which represented by the formula (VIII):

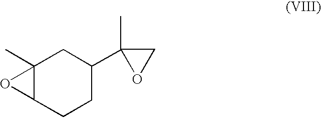

Examples of the multifunctional epoxy compound may be at least one compound selected from the group consisting of epoxy compounds of the following general formula (VI):

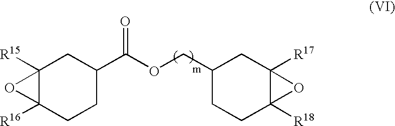

wherein R¹⁵, R¹⁶, R¹⁷ and R¹⁸ represent each independently hydrogen, methyl or ethyl and m represents an integer of 1 to 8.

Examples of the multifunctional epoxy compound may be at least one compound selected from the group consisting of epoxy compounds of the following general formula (VII):

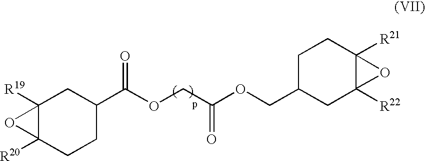

Wherein R¹⁹, R²⁰, R²¹ and R²² represent each independently hydrogen, methyl or ethyl and p represents an integer of 1 to 8.

As deterioration in sensitivity and resolution of the resist composition obtained can be prevented, it is the most preferable to use the epoxy compound of the formula (V), especially the compound of the formula (VIII) among the aforementioned multifunctional epoxy compounds.

Specific examples of the epoxy compounds represented by the formulae (V), (VI) or (VII) include following formulae:

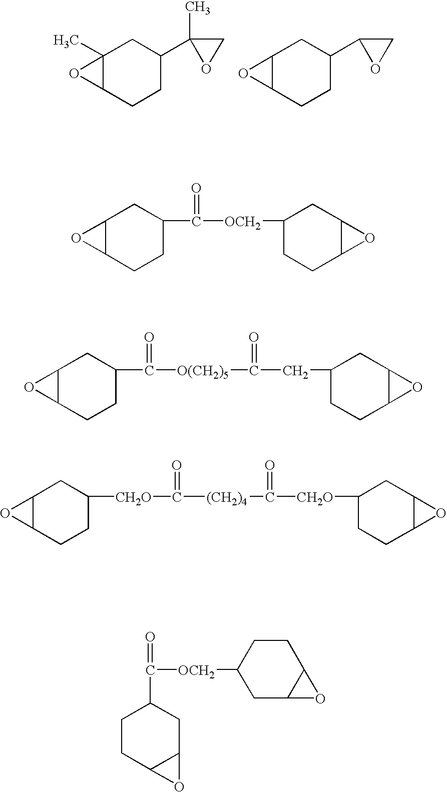

Specific examples of other epoxy compounds to be used include the following formulae:

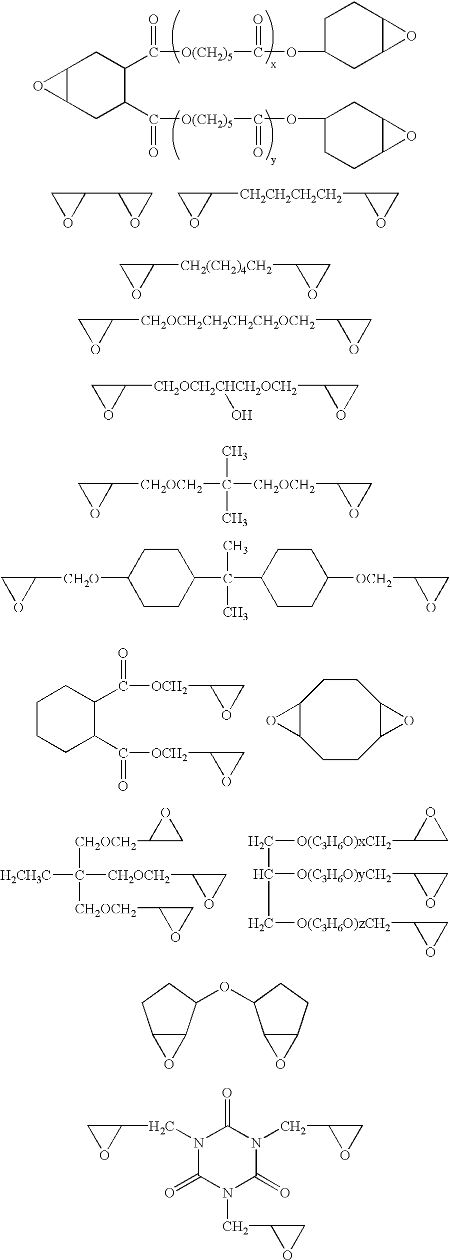

It is preferable that the positive resist composition of the present invention contains the acid generating agent in an amount of 0.1 to 20 parts by weight and the multifunctional epoxy compound in an amount of 0.01 to 5 parts by weight based on 100 parts by weight of the present resin composition.

When the basic compound is used as a quencher, it is preferable that the composition of the present invention contains the basic compound in an amount of 0.001 to 1 part by weight based on 100 parts by weight of the present resin component.

The present resist composition of the present invention can also contain small amount of various additives such as sensitizers, solution suppressing agents, surfactants, stabilizers, dyes and the like, if necessary.

The resist composition of the present invention is usually used as a liquid containing the above-mentioned components dissolved in a solvent, and the liquid is applied on a substrate such as a silicon wafer and the like according to an ordinary method such as spin coating and the like.

Any solvent may be used as long as they dissolve each component, show suitable drying speed, and give a uniform and smooth film after evaporation of the solvent. Solvents generally used in this field can be used as the solvent.

Examples thereof include glycol ether esters such as ethylcellosolve acetate, methylcellosolve acetate, propylene glycol monomethyl ether acetate and the like; ethers such as diethyleneglycol dimethyl ether and the like; esters such as ethyl lactate, butyl acetate, amyl acetate, ethyl pyruvate and the like; ketones such as acetone, methyl isobutyl ketone, 2-heptanone, cylohexanone and the like; and cyclic esters such as γ-butyrolactone and the like. These solvents can be used each alone or in combination of two or more.

On a resist film applied on a substrate and dried, exposure treatment for patterning is performed, then, heating treatment for promoting a protective group-removing reaction (post bake exposure) is conducted. Thereafter, the resist film is developed with an alkali developer. The alkali developer used can be selected from various alkaline aqueous solutions used in this field, and generally, often used are aqueous solutions of tetramethylammonium hydroxide and (2-hydroxyethyl)trimethylammonium hydroxide (so-called “choline”).

The following examples will illustrate the present invention further specifically, but do not limit the scope of the present invention at all. In examples, parts representing content or use amount are by weight unless otherwise stated. The weight-average molecular weight (Mw) and polydispersion (Mw/Mn) were measured by gel permeation chromatography using polystyrene as a standard.

### Resin Synthesis Example 1

### Synthesis Example of resin A1

Into a flask with 50 g of DMF were charged 10 g of poly 5-norbornene-2-(2,2-ditrifluoromethyl-2-hydroxy)ethyl and dissolved to make a solution. After adding and dissolving 1.89 g of potassium iodide in the solution, 6.30 g of anhydrous potassium carbonate was added thereto. After adding 0.88 g of methoxymethyl chloride dropwise, the resulting solution was stirred for 10 hours at room temperature to complete the reaction. After the reaction, 150 g of methyl isobutyl ketone was added to the reaction mixture and the mixture was washed with water several times. The organic layer was concentrated, then, charged into n-hexane to obtain precipitate. The precipitate was decanted and dried under reduced pressure to obtain a resin with average molar weight of 13,000. The methoxymethylated ratio of the resin was analyzed by a nuclear magnetic resonance (¹H-NMR) analyzer to be about 25%. Herein after, the resin is referred to as Resin 1.

### Examples 1 to 3 and Comparative Example 1

The following components were mixed and dissolved and the solution was filtered through a fluororesin filter having pore diameter of 0.2 μm to prepare a resist solution.

| | | |
|---|---|---|
| Resin: Resin A | 10 | parts |
| Acid generating agent: p-tolyldiphenylsulfonium | 0.2 | part |
| perfluorooctanesulfoante | | |
| Quencher: tetrabutylammonium hydroxide | 0.015 | part |
| Multifunctional epoxy compound: A compound of the | | |
| following formula (VIII) (“CELOXIDE” manufactured by | | |
| Daicel Chemical Co., Ltd.) (amount is shown in Table 1) | | |
| 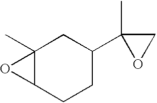 | | |
| Solvent: propylene glycol monomethyl ether acetate | 57 | parts |
| γ-butyrolactone | 3 | parts |

Properties in Sensitivity and Resolution

“DUV-30J-11” which is a composition for organic reflection preventing film manufactured by Nissan Chemical Industries, Ltd. was applied and baked at 215° C. for 60 seconds to form an organic reflection preventing film having a thickness of 780 Å on a silicon water, and on this, the resist solution prepared above was spin-coated so that the film thickness after drying was 0.19 μm. After application of the resist solution, prebake was conducted at 160° C. for 60 seconds on a direct hot plate. The wafer on which the resist film had thus been formed was exposed to line and space pattern using ArF excimer stepper (“NSR ArF” manufactured by Nikon Corp., NA=0.55, σ=0.6) while changing the exposure amount stepwise.

After exposure, post exposure bake was conducted at 130° C. for 60 seconds on a hot plate, further, paddle development was conducted for 60 seconds with 2.38 wt % tetramethylammonium hydroxide aqueous solution.

Line and space pattern on the organic reflection preventing film substrate after development was observed by a scanning electron microscope, and the effective sensitivity and resolution were checked by the following methods. The results are shown in Table 1.

Effective sensitivity: It is represented by exposure amount under which line and space pattern of 0.18 μm shows a ratio of 1:1.

Resolution: It is represented by the minimum size of line and space pattern separating at the exposure amount of the effective sensitivity.

Measurement of Durability Against Dry Etching

The resist solution prepared above was spin-coated on the silicon wafer treated with hexamethylsilazane so that the film thickness after drying was between 0.3 and 0.5 μm. After application of the resist solution, prebake was conducted at 160° C. for 60 seconds on a direct hot plate. The wafer on which the resist film had thus been formed was etched for 4 minutes using DEM-451 (manufactured by ANERVA Co., Ltd.) under the conditions in which the flow rate of the mixed gas was 2.5 sccm of oxygen and 50 sccm of CHF₃, the pressure was 16 Pa and INCIDENSE POWER was 250 W. The difference of thickness of the film between before and after etching was shown as the ratio to the difference of novolac resin. Smaller value of said ratio indicates higher durability against dry etching. The thickness of the film was measured by RAMDA ACE (manufactured by DAINIPPON SCREEN MFG. CO., LTD.) The results are shown in Table 1.

Measurement of Transmittance

The resist solution prepared above was applied on a magnesium fluoride wafer so that the film thickness after drying was 0.1 μm, and prebake was conducted at 160° C. for 60 seconds on a direct hot plate to form a resist film. The transmittance at a wavelength of 157 nm of thus formed resist film was measured using a vacuum ultraviolet spectrometer (manufactured by Nippon Bunko K.K.). The results are shown in Table 1.

TABLE 1

| | Amount | | | | ROTRANS |
|---|---|---|---|---|---|
| | of | | | | (%) |
| | MFEC | ESENS | RESO | | 157 nm |
| Exp. No. | (parts) | (mJ/cm²) | (μm) | RODADE | TOF/1000Å |
| Exp. l | 0.5 | 16 | 0.15 | 1.50 | 64.1 |
| Exp. 2 | 1.0 | 16 | 0.15 | 1.41 | 63.3 |
| Exp. 3 | 2.0 | 16 | 0.15 | 1.37 | 64.9 |
| Comp. Exp. 1 | 0 | 15 | 0.15 | 1.62 | 64.8 |

Exp.: Example,

Comp. Exp.: Comparative Example,

MFEC: Multifunctional Epoxy Compound

ESENS: Effective Sensitivity

RESO: Resolution

RODADE: Ratio of Durability against Dry Etching relative to resist for I ray

ROTRANS: Ratio of Transmittance

TOF: Thickness of Film

As apparent from Table 1, the resists of the examples show excellent durability against dry etching as well as good balance in resolution and sensitivity. Further, as decrease of the rate of transmittance at a wavelength of 157 nm can not be observed by the addition of the multifunctional epoxy compound, the resist composition can be applied to F₂ laser technology.

The chemical amplification type positive resist composition of the present invention shows good balance in resolution and sensitivity and high durability against dry etching. Therefore, this composition can manifest excellent abilities as a resist for KrF eximer laser, ArF eximer laser, F₂ laser.

What is claimed is:

1. A chemical amplification type positive resist composition comprising a resin having structural units of the following general formulae (I) and (II) and insoluble or poorly soluble itself in an alkali aqueous solution but becoming soluble in an alkali aqueous solution by the action of an acid; an acid generating agent; and a multifunctional epoxy compound: 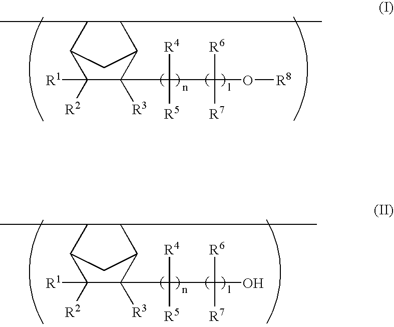
wherein, R¹, R² and R³ represent each independently hydrogen, halogen, hydroxyl group, alkyl group having 1 to 14 carbon atoms, alicyclic group or lactone ring group,
wherein at least one hydrogen on the alicyclic group or on the lactone ring group may independently be substituted by halogen, hydroxyl group or alkyl group and at least one hydrogen on the alkyl group may independently be substituted by halogen, hydroxyl group or alicyclic ring group;
n and 1 represent each independently an integer of 0 to 4;
R⁴ and R⁵represent each independently hydrogen or alkyl group having 1 to 4 carbon atoms; and
either or both of R⁶ and R⁷ represent fluoroalkyl group having 1 to 6 carbon atoms and when both of R⁶ and R7 do not represent said fluoroalkyl group, rest of R⁶ and R⁷ represents hydrogen or alkyl group having 1 to 6 atoms; and
R⁸ represents an acid-unstable group dissociating in the presence of an acid.

2. The chemical amplification type positive resist composition according to claim 1, wherein said resin further having structural unit of the following general formula (III): 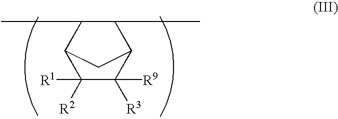
wherein R¹, R², R³, R⁴, R⁵, R⁶, R7, and R⁸ represent the same as defined above; and
R⁹ represent hydrogen, halogen, alkyl group having 1 to 14 carbon atoms, alicyclic group or lactone ring group,
wherein at least one hydrogen on the alicyclic group or the lactone ring group may independently be substituted by halogen or alkyl group and at least one hydrogen on the alkyl group may independently be substituted by halogen, or alicyclic ring group.

3. The chemical amplification type positive resist composition according to claim 1, wherein said multifunctional epoxy compound is at least one compound selected from the group consisting of epoxy compounds of the following general formula (V): 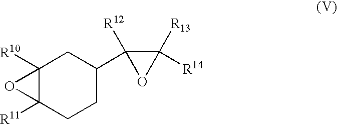
wherein R¹⁰, R¹¹, R¹² and R¹⁴ represent each independently hydrogen, methyl or ethyl.

4. The chemical amplification type positive resist composition according to claim 1, wherein said multifunctional epoxy compound is at least one compound selected from the group consisting of epoxy compounds of the following general formula (VI): 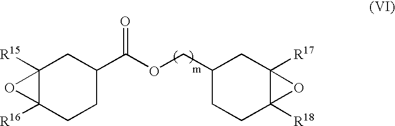
wherein R¹⁵, R¹⁶, R¹⁷ and R¹⁸ represent each independently hydrogen, methyl or ethyl and m represents an integer of 1 to 8.

5. The chemical amplification type positive resist composition according to claim 1, wherein said multifunctional epoxy compound is at least one compound selected from the group consisting of epoxy compounds of the following general formula (VII): 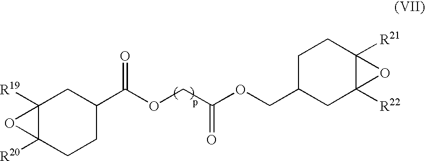
Wherein R¹⁹, R²⁰, R²¹ and R²² represent each independently hydrogen, methyl or ethyl and p represents an integer of 1 to 8.

6. The chemical amplification type positive resist composition according to claim 1, wherein said multifunctional epoxy compound is an epoxy compound of the formula (V), wherein R¹⁰ and R¹² represent methyl, and R¹¹, R¹³ and R¹⁴ represent hydrogen.

7. The chemical amplification type positive resist composition according to claim 1, wherein the content of the acid generating agent is from 0.1 to 20 parts by weight and the content of the multifunctional epoxy compound is from 0.01 to 5 parts by weight based on 100 parts of the resin insoluble or poorly soluble itself in an alkali aqueous solution but becoming soluble in an alkali aqueous solution by the action of an acid.

8. The chemical amplification type positive resist composition according to claim 1 or 2, wherein the content of the structural unit of the formula (I) is from 0.15 to 0.5 mole based on one mole of total content of structural units of the formula (I), (II) and (III).

9. The chemical amplification type positive resist composition according to claim 1, which further comprises a basic compound as a quencher.

10. The chemical amplification type positive resist composition according to claim 9, wherein the content of the basic compound is from 0.001 to 1 part by weight based on 100 parts by weight of the resin insoluble or poorly soluble itself in an alkali aqueous solution but becoming soluble in an alkali aqueous solution by the action of an acid.

11. The chemical amplification type positive resist composition according to claim 1 or 2, wherein the resin having the structural units of the formulae (I) and (II) is obtained by partially substituting an acid-unstable group dissociating in the presence of an acid for hydrogen of hydroxyl group in a resin having a structural unit of the formula (II).
